(19) United States
(12) Patent Application Publication
(10) Pub. No.: US 2021/0116799 A1
(43) Pub. Date: Apr. 22, 2021

(54) Multilayer Reflector And Methods Of Manufacture And Patterning

(71) Applicant: Applied Materials, Inc., Santa Clara, CA (US)

(72) Inventors: Lei Zhong, Niskayuna, NY (US); Ho-yung David Hwang, Cupertino, CA (US)

(21) Appl. No.: 17/071,331

(22) Filed: Oct. 15, 2020

Related U.S. Application Data
(60) Provisional application No. 62/916,951, filed on Oct. 18, 2019.

(51) Int. Cl. G03F 1/24; H01L 21/033

(52) U.S. Cl. CPC G03F 1/24; H01L 21/0337; H01L 21/0332

(57) ABSTRACT

Extreme ultraviolet (EUV) hard masks and methods for their manufacture are disclosed. The EUV hardmasks comprise a substrate, a multilayer stack of alternating reflective layers on the substrate, and a photoresist layer on the multilayer stack. The alternating reflective layers comprise silicon and a nonmetal. Methods of transferring a pattern to a substrate are also disclosed.

### CROSS-REFERENCE TO RELATED APPLICATIONS

The present disclosure claims priority to United States provisional application Ser. No. 62/916,951, filed on Oct. 18, 2019, the entire content of which is incorporated herein by reference.

### TECHNICAL FIELD

The present disclosure relates generally to EUV multilayer reflectors and methods of manufacturing EUV reflectors. In specific embodiments, multilayer reflectors, methods of manufacturing EUV reflectors and methods for transferring a pattern to a substrate with reduced EUV dose.

### BACKGROUND

Photolithographic techniques are used in the fabrication of semiconductor devices to transfer a pattern (e.g., a circuitry pattern) to a wafer using light or other wavelengths of electromagnetic radiation. The light passes through, or is reflected off of, a mask which defines the pattern. Light from the mask projects an image of the pattern onto the wafer. The wafer is coated with a layer of a photosensitive material, referred to as a photoresist or resist, which undergoes a chemical reaction when exposed to light. After exposure, the resist is baked and developed, leaving regions of the wafer surface covered resist and complementary regions exposed.

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. Multilevel interconnects require precise imaging and placement of high aspect ratio features, such as vias and other interconnects. Reliable formation of these interconnects is needed to achieve further increases in device and interconnect density. One process used to form various interconnects and other semiconductor features uses EUV (extreme ultraviolet) lithography. Conventional EUV patterning uses a multilayer stack in which a photoresist is patterned on top of a hardmask. Common hardmask materials are spin-on silicon anti-reflective coating (SiARC) and a deposited silicon oxynitride (SiON).

Processing of EUV lithography generally takes a significant amount of exposure time and requires large amounts of energy. The resolution and efficiency of photolithographic systems may be affected by the amount of light coupled into the photoresist. The optical absorbance of photoresist materials used in lithography increases with decreasing wavelength, especially in the extreme ultraviolet (EUV) at wavelengths of ˜13.5 nm. For example, each EUV photon carries fourteen times as much energy as an ArF photon, and therefore for EUV lithography, many fewer photons are available to catalyze resist polarity changes in the resist. As a result, less light reaches the underlying substrate (˜50% in the EUV), when the photoresist is thick (>100 nm). For thinner photoresist, however, the absorption is greatly reduced. Consequently a substantial amount of incident EUV photons will go unabsorbed. A decreasing index of refraction mismatch between the photoresist and the underlying substrate also reduces reflections from the substrate back into the photoresist. The net effect is wasted photons. To increase processing throughputs, new high performance photoresist materials have been developed. However, it would be desirable to provide alternative options and processing methods that allow for decreased dose time and/or lower dose energies for EUV lithography.

### SUMMARY

One or more embodiments of the disclosure are directed to article comprising a substrate, a multilayer reflector stack on the substrate comprising alternating layers of a first reflective layer of silicon and a second reflective layer of a nonmetal, and a photoresist layer on the multilayer reflector stack. In one or more embodiments, the multilayer reflector stack is reflective of EUV radiation, for example, at a wavelength of 13.5 nm. In one or more embodiments, the article comprises an EUV hardmask.

Additional embodiments of the disclosure are directed to a method of manufacturing an article, for example, an EUV hardmask. The method comprises forming a multilayer reflector stack on the substrate comprising alternating layers of a first reflective layer of silicon and a second reflective layer of a nonmetal, and forming a photoresist layer on the multilayer reflector stack.

Further embodiments of the disclosure are directed to a method for transferring a pattern to a substrate, for example, a semiconductor substrate, the method comprises applying a multilayer reflector comprising alternating reflective layers of silicon and a nonmetal above a surface of the substrate, applying a photoresist to a surface of multilayer reflector stack, and directing extreme ultraviolet energy toward the photoresist.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates a hardmask according to an embodiment of the disclosure;

FIG. 2 shows reflectivity of a multilayer stack of alternating Si/Mo and Si/C reflective layer pairs; as a function of the number of pairs;

FIG. 3 shows the estimated dose reduction as a function of photoresist thickness by a reflector of the reflectivity from 10% to 65%;

FIG. 4 shows the reflectivity as a function of the carbon film density for a reflector of 15, 20 and 40 Si—C pairs, respectively; and

FIG. 5 shows an example of wafer process flow according to an embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “horizontal” as used herein is defined as a plane parallel to the plane or surface of a substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” indicates that there is direct contact between elements. The term “directly on” indicates that there is direct contact between elements with no intervening elements.

Those skilled in the art will understand that the use of ordinals such as “first” and “second” to describe process regions do not imply a specific location within the processing chamber, or order of exposure within the processing chamber.

As used in this specification and the appended claims, the term “substrate” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate means both a bare substrate and a substrate with one or more films or features deposited or formed thereon.

According to one or more embodiments, an EUV hardmask including a multilayer reflector and method of making the same are provided. Embodiments provide a multilayer reflector and method which increase the EUV photons available for the resist absorption without making any change to the resist itself. In one or more embodiments, EUV lithography is simplified by taking extremely complicated resist chemistry changes out of the equation. In other words, the multilayer reflector disclosed according to one or more embodiments can be applied to many commercially available EUV resists, including both chemically amplified resists (CAR) and inorganic resists.

According to one or more embodiments, a “substrate” refers to any substrate or material surface formed on a substrate upon which film processing is performed during a fabrication process. In addition to film processing directly on the surface of the substrate itself, in one or more embodiments, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

EUV lithography generally requires a significant amount of exposure time and uses large amounts of energy. Some embodiments of the disclosure advantageously provide methods and multilayers to reduce the energy and/or exposure time required for EUV lithography. One or more embodiments of the disclosure provide multilayers and methods for producing multilayers which provide ample secondary electrons when excited by EUV radiation.

Lithography may be performed using various frequencies of electromagnetic radiation. Radiation transmitted from a patterned mask may be coupled into a photoresist material on a wafer. The exposed portions of the photoresist undergo a chemical reaction, e.g., by photosolubization in positive resists or polymerization in negative resists. The amount of energy (photons) coupled to the photoresist may affect system throughput, pattern transfer, and resolution.

Because reflections occur at interfaces when there is an index of refraction mismatch between the materials on each side of the interface, in deep UV (DUV) lithography reflections from the top and bottom resist interfaces may be so strong that prominent standing waves may be created in the resist. Photons may be absorbed in a first pass as the light enters the photoresist and in a second pass as photons are reflected from the substrate surface. To improve resolution and critical dimension (CD) control, standing waves may be minimized in DUV lithography by the use of anti-reflective hardmasks (bottom ARCS) to control the reflectivity at the interface.

At EUV frequencies such as 13.5 nm, however, standing waves do not pose a problem because of two reasons. First, there are very few reflections from the resist-substrate interface because the real part of the index of refraction of materials is close to 1. The lack of reflection means that the energy absorbed in a layer of photoresist in EUV lithography systems occurs only during a single pass of EUV photons through the resist. Second, the vertical distance between a maximum and an adjacent minimum in a standing wave is a quarter of the wavelength, which is very small in the case of EUV and substantially smaller than the typical acid diffusion length. The acid diffusion could smooth out the standing-wave in the subsequent photo-resist process step.

The resist materials typically used in EUV lithography have a high absorbance of energy. Consequently, much of the EUV energy is absorbed in the upper portions of the resist. Together with the lack of a reflection in EUV, the high absorbance of the resist at EUV frequencies results in the lower portions of the resist receiving little of the EUV energy. This, in turn, may cause problems in producing vertical sidewalls in the resist pattern; the top of the resist receives more energy than the bottom so, in a positive resist, the top of the channel (areas that will clear after the develop step) will be wider than the bottom. Conversely, in a negative resist, the top of the channel will be narrower than the bottom.

These undesirable results may be reduced by, for example, redirecting some of the energy that reaches the lower surface of the photoresist back into the photoresist. In one or more embodiments, a hardmask is provided comprising a multilayer reflector stack comprised of alternating layers of silicon and a nonmetal. Examples of nonmetals include carbon, phosphorus, sulfur, selenium, and combinations of one or more of carbon, phosphorus sulfur and selenium.

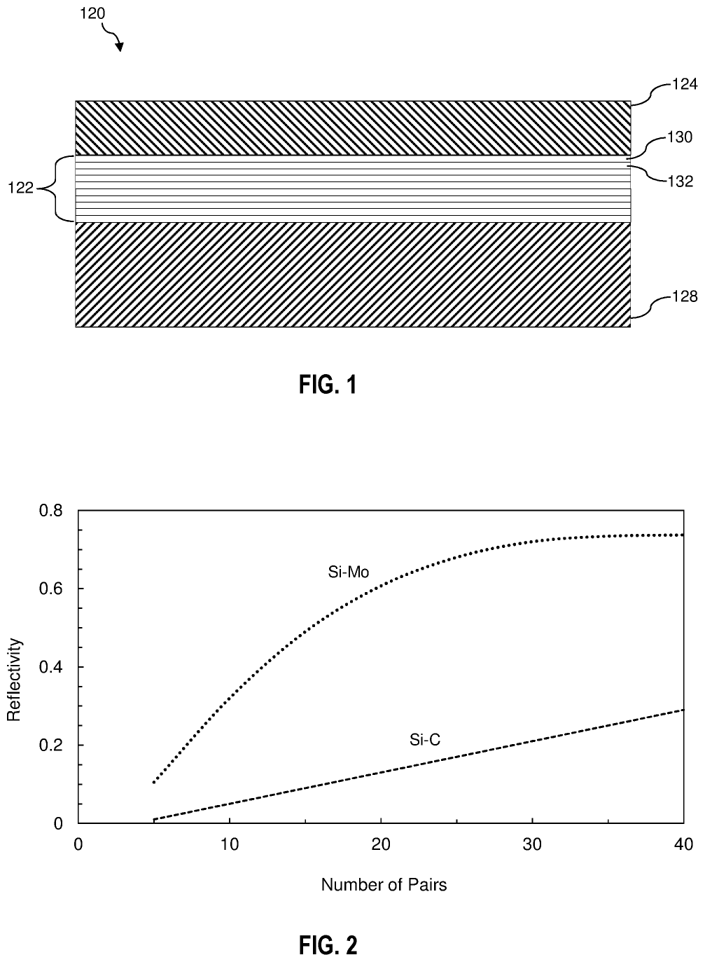

Referring now to FIG. 1, an exemplary embodiment of a hardmask 120 comprises a substrate 128, a multilayer reflector stack 122, and a photoresist layer 124. The multilayer reflector stack 122 comprises a first reflective layer 130 that is silicon and a second reflective layer 132 that is a nonmetal as provided above. The first reflective layer 130 and the second reflective layer 132 are arranged in an alternating stack as shown in FIG. 1.

In one or more embodiments, the substrate 128 comprises a substrate material that is typically used in photolithography. Examples of substrate materials include silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Examples of semiconductor wafers comprise comprises a semiconductor materials, e.g., silicon (Si), carbon (C), germanium (Ge), silicon germanium (SiGe), gallium arsenide (GaAs), indium phosphide (InP), indium gallium arsenide (InGaAs), aluminum indium arsenide (InAlAs), other semiconductor material, or any combination thereof. In an embodiment, the substrate is a semiconductor-on-isolator (SOI) substrate.

Substrates may be exposed to a pretreatment process to polish, etch, reduce, oxidize, hydroxylate, anneal, UV cure, e-beam cure and/or bake the substrate surface.

In one or more embodiments, the first reflective layer 130 and the second reflective layer 132 have dissimilar optical constants for the extreme ultraviolet light. The alternating first reflective layer 130 and second reflective layer 132 provide a resonant reflectivity when the period of the thickness of the alternating first reflective layer 130 and second reflective layer 132 is one half the wavelength of the extreme ultraviolet light. In one or more embodiments, for the extreme ultraviolet light at a wavelength of 13.5 nm, the alternating first reflective layer 130 and second reflective layer 132 have a combined thickness of 6.9 nm.

In one or more embodiments, the second reflective layer comprises a nonmetal material having a refractive index that is less than 1 at 13.5 nm. Examples of nonmetals include carbon, phosphorus, sulfur, selenium, and combinations of one or more of carbon, phosphorus sulfur and selenium.

In specific embodiments, the first reflective layer is silicon and the second reflective layer is carbon. In one or more embodiments, the second reflective layer is amorphous diamond-like carbon having a refractive index less than 0.97 and greater than 0.90, for example in a range of from 0.91 to 0.95, for example in a range of from 0.92 to 0.94 at a wavelength of 13.5 nm. In one or more embodiments, the second reflective layer is amorphous diamond-like carbon having a content of sp³ hybridized carbon atoms greater than 40 percent and a refractive index greater than 0.9 and less than 0.97 at a wavelength of 13.5 nm. An example of such an amorphous diamond-like carbon is described in United States Patent Application Publication Number US20180354804.

The multilayer reflector stack 122 of alternating first reflective layer 130 and second reflective layer 132 can be formed in a variety of ways. In an embodiment, the alternating first reflective layer 130 and second reflective layer 132 are formed by magnetron sputtering, ion sputtering systems, pulsed laser deposition, cathode arc deposition, or a combination thereof.

In an illustrative embodiment, the multilayer reflector stack 122 is formed using a physical vapor deposition technique, such as magnetron sputtering. In an embodiment, the alternating first reflective layer 130 and second reflective layer 132 of the multilayer reflector stack 122 have the characteristics of being formed by the magnetron sputtering technique including precise thickness, low roughness, and clean interfaces between the layers. In an embodiment, the alternating first reflective layer 130 and second reflective layer 132.

The physical dimensions of the alternating first reflective layer 130 and second reflective layer 132 of the multilayer reflector stack 122 formed using the physical vapor deposition technique can be precisely controlled to increase reflectivity. In an embodiment, the first reflective layer 130 of silicon has a thickness of 4.1 nm. The second reflective layer 132, such as a layer of a nonmetal, has a thickness of 2.8 nm. The thickness of the layers dictates the peak reflectivity wavelength of the extreme ultraviolet reflective element. If the thickness of the layers is incorrect, the reflectivity at the desired wavelength of 13.53 nm can be reduced.

FIG. 2 shows reflectivity for various reflective layer pairs. As shown in FIG. 2, the reflectivity of a Si/nonmetal multilayer stack (e.g. Si/C) can be tuned by adjusting the number of layers.

In one or more embodiments, the photoresist layer 124 comprises a resist material that is typically used in EUV lithography. For example, the photoresist layer 124 may comprise chemically amplified resists (CAR) or inorganic resists. The photoresist layer 124 in some embodiments comprises a chemically amplified resist that is reactive to relatively low dosages of activation energy. For example, the photoresist layer may comprise any of a number of chemically amplified resists such as N-tert-butoxycarbonyl (t-BOC) protected PMMA resist containing photo-acid generators.

In one or more embodiments, the photoresist has a thickness in a range of from about 10 nm to about 60 nm, from about 10 nm to about 55 nm, from about 10 nm to about 50 nm, from about 10 nm to about 45 nm, from about 10 nm to about 40 nm, from about 10 nm to about 35 nm, from about 10 nm to about 30 nm, from about 10 nm to about 20 nm, from about 20 nm to about 60 nm, from about 20 nm to about 50 nm, from about 20 nm to about 40 nm or about 20 nm to about 30 nm.

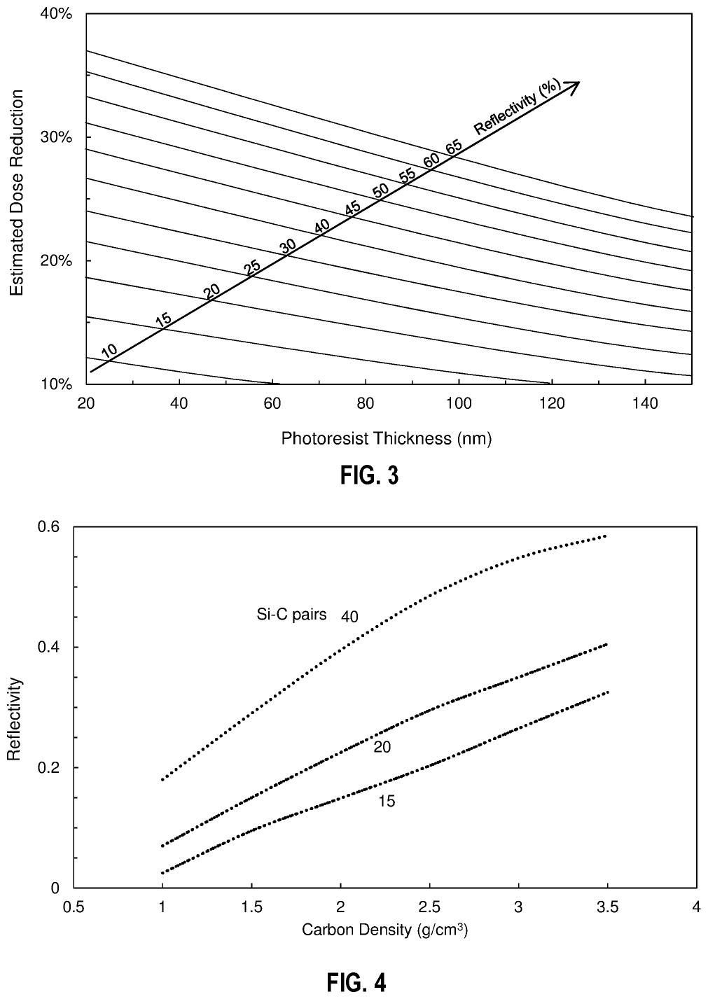

Referring now to FIG. 3, according to one or more embodiments, it has been discovered that when the thickness of the photoresist is in the above ranges, a multilayer reflector stack comprising alternating Si/nonmetal layers, for example alternating Si/C layers, achieves a >10% EUV dose reduction, even with a moderate reflectivity of 20% and below. In FIG. 3, a photoresist absorbance of 5 μm⁻¹ is assumed. According to one or more embodiments, significantly greater dose reduction is achievable through enhancement of the reflectivity of a Si/C multi-layer reflector, which can be achieved through carbon film densification.

FIG. 4 shows reflectivity as a function of the carbon film density for a reflector comprised of 15, 20 and 40 Si—C pairs, respectively. According to one or more embodiments, a high density carbon film can be made through promoting diamond-like amorphous carbon having a content of sp³ hybridized carbon atoms greater than 40 percent. Thus, according to an aspect of the disclosure, a method of manufacturing an article including a multilayer reflector stack includes the step of forming a carbon layer as part of a Si/C alternating layer multilayer reflector stack, wherein the density of the carbon layer is adjusted to change the reflectivity of the of multilayer reflector stack. The density of the carbon according to one or more embodiments is varied in a range from 1 g/cm³ to 3.5 g/cm³. In some embodiments, the density of the carbon layer is increased to improve reflectivity. In some embodiments, the carbon comprises amorphous carbon with amorphous carbon having a content of sp³ hybridized carbon atoms greater than 40 percent. In some embodiments, the amorphous carbon has a refractive index in a range of from 0.92 to 0.97 at a wavelength of 13.5 nm. It was discovered that providing a Si/C multilayer in the above manner can reduce EUV dosage by greater than about 10%.

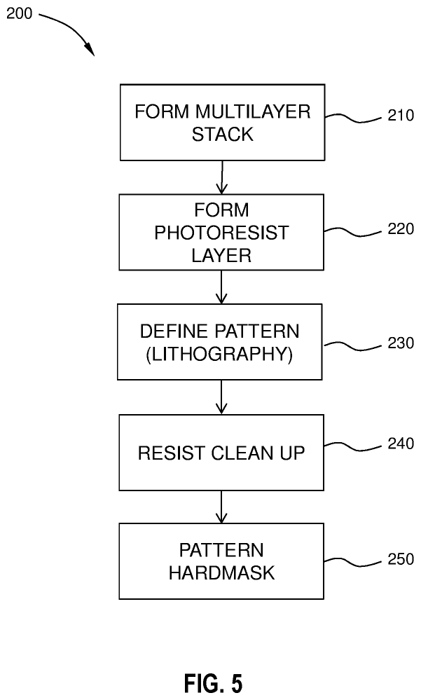

Another aspect of the disclosure pertains to method of making an article, for example, an EUV hardmask, and some embodiments comprise patterning a substrate. Referring to FIG. 5, an exemplary embodiment of a method comprises at 210 forming a multilayer reflector stack on the substrate comprising alternating layers of a first reflective layer of silicon and a second reflective layer of a nonmetal. At 220, the method includes forming a photoresist on the multilayer stack. The photoresist layer can have the attributes according to any of the embodiments described above. The multilayer reflector stack can have any of the features described above.

In one or more embodiments, the method 200 can include defining a pattern in the photoresist 230. Patterning the photoresist can be done by any suitable lithography process known to the skilled artisan. In some embodiments, patterning the photoresist comprises exposing the photoresist to a patterned EUV radiation source and a developer. The developer can remove a portion of the photoresist to expose portions of the middle layer. In some embodiments, the photoresist is a negative tone photoresist and the developer removes portions of the photoresist not exposed to the radiation source. In some embodiments, the photoresist is a positive tone photoresist and the developer removes portions of the photoresist that have been exposed to the radiation source.

The photoresist of some embodiments comprise one or more of an organic photoresist or a metal oxide photoresist. In some embodiments, the organic resist comprises an organic photoresist, also referred to as a chemically amplified resist (CAR). In some embodiments, the photoresist comprises a metal oxide photoresist. In some embodiments, the metal oxide comprises a metal atom and one or more of carbon (C), hydrogen (H), oxygen (0) or nitrogen (N).

At 240, the resist is cleaned up, where any residue is removed in a cleaning process to form patterned photoresist. At 250, the hardmask is patterned.

In one or more embodiments, a method for transferring a pattern to a substrate, for example, a semiconductor substrate, the method comprises applying a multilayer reflector stack comprising alternating reflective layers of silicon and a nonmetal above a surface of the substrate, applying a photoresist to a surface of the multilayer reflector stack, and directing extreme ultraviolet energy toward the photoresist. In some embodiments of the method, the second reflective layer is selected from the group consisting of carbon, phosphorus, sulfur, selenium, and combinations thereof. In some embodiments of the method, the second reflective layer has a refractive index of less than 1. In some embodiments of the method, the second reflective layer is carbon, for example, amorphous carbon, and as a specific example, amorphous carbon having a content of sp³ hybridized carbon atoms greater than 40 percent. In some embodiments, the amorphous carbon has a refractive index in a range of from 0.92 to 0.97 at a wavelength of 13.5 nm. In some embodiments, the photoresist layer has a thickness in a range of from 10 nm to about 60 nm, or any of the ranges provided above.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. An article comprising:
a substrate;
a multilayer reflector stack on the substrate comprising alternating layers of a first reflective layer of silicon and a second reflective layer of a nonmetal; and
a photoresist layer on the multilayer reflector stack.

2. The article of claim 1, wherein the second reflective layer is selected from the group consisting of carbon, phosphorus, sulfur, selenium, and combinations thereof.

3. The article of claim 1, wherein the article comprises an EUV hardmask and the multilayer reflector stack is reflective of EUV radiation.

4. The article of claim 2, wherein the second reflective layer has a refractive index of less than 1.

5. The article of claim 4, wherein the second reflective layer is carbon.

6. The article of claim 5, wherein the second reflective layer is amorphous carbon.

7. The article of claim 6, wherein the amorphous carbon having a content of sp³ hybridized carbon atoms greater than 40 percent.

8. The article of claim 5, wherein the amorphous carbon has a refractive index in a range of from 0.92 to 0.97 at a wavelength of 13.5 nm.

9. The article of claim 8, wherein the photoresist layer has a thickness in a range of from 10 nm to about 60 nm.

10. A method of manufacturing an extreme ultraviolet (EUV) hardmask:
forming a multilayer reflector stack on the substrate comprising alternating layers of a first reflective layer of silicon and a second reflective layer of a nonmetal; and
forming a photoresist layer on the multilayer reflector stack.

11. The method of claim 10, wherein the second reflective layer is selected from the group consisting of carbon, phosphorus, sulfur and combinations thereof.

12. The method of claim 11, wherein the second reflective layer has a refractive index of less than 1.

13. The method of claim 12, wherein the second reflective layer is amorphous carbon.

14. The method of claim 13, wherein the amorphous carbon comprises a content of sp³ hybridized carbon atoms greater than 40 percent.

15. The method of claim 14, wherein the amorphous carbon has a refractive index in a range of from 0.92 to 0.97 at a wavelength of 13.5 nm.

16. The method of claim 15, wherein the photoresist layer has a thickness in a range of from 10 nm to about 60 nm.

17. A method for transferring a pattern to a substrate, the method comprising:
applying a multilayer reflector stack comprising alternating layers of a first reflective layer of silicon and a second reflective layer of a nonmetal;
applying a photoresist to a surface of the multilayer reflective stack; and
directing extreme ultraviolet energy toward the photoresist.

18. The method of claim 17, wherein the second reflective layer is selected from the group consisting of carbon, phosphorus, sulfur, selenium, and combinations thereof.

19. The method of claim 18, wherein the second reflective layer has a refractive index of less than 1.

20. The method of claim 19, wherein the second reflective layer is carbon.
